(19) United States
(12) Patent Application Publication
(10) Pub. No.: US 2003/0216041 A1
(43) Pub. Date: Nov. 20, 2003

(54) In-situ thermal chamber cleaning

(76) Inventors: Robert B. Herring, San Jose, CA (US); Joseph C. Sisson, Watsonville, CA (US); Yoshihide Senzaki, Aptos, CA (US)

Correspondence Address: DORSEY & WHITNEY LLP, INTELLECTUAL PROPERTY DEPARTMENT, 4 EMBARCADERO CENTER, SUITE 3400, SAN FRANCISCO, CA, 94111, US

(21) Appl. No.: 10/318,664

(22) Filed: Dec. 12, 2002

Related U.S. Application Data
(60) Provisional application No. 60/379,381, filed on May 8, 2002.

(51) Int. Cl. H01L 21/302; H01L 21/461

(52) U.S. Cl. 438/689

(57) ABSTRACT

A cost-effective and environmentally benign cleaning method is provided which comprises introducing an etch gas into the chamber, performing a first cleaning process to remove the deposited materials at a high rate, and performing a second cleaning process to remove the deposited materials at a high etch selectivity with respect to the materials forming the chamber. The first cleaning process is performed at a first pressure, the second cleaning process is performed at a second pressure. The second pressure is substantially lower than the first pressure to enhance the etching selectivity.

### RELATED APPLICATION

This application claims priority to the U.S. Provisional Patent Application Serial No. 60/379,381, filed May 8, 2002, the disclosure of which is hereby incorporated by reference in its entirety.

### FIELD OF THE INVENTION

The present invention relates generally to semiconductor processing, and more particularly to systems and methods for thermally cleaning semiconductor apparatus.

### BACKGROUND OF THE INVENTION

Single-wafer rapid thermal processing (RTP) is potentially an alternative to conventional furnace processing for integrated circuit device fabrication, especially as the future wafer size moves toward 300 mm for cost reduction. Single-wafer RTP provides shorter process cycle time and better wafer temperature uniformity. A hot-wall RTP apparatus for low pressure chemical vapor deposition (LPCVD) that processes single-wafer to produce silicon oxides, silicon nitrides, silicon oxynitride, and the like has been developed, as described in the U.S. patent application Ser. No. 10/106,677, filed Mar. 25, 2002, entitled “System and Method for Improved Thin Dielectric Films”, the disclosure of which is herein incorporated by reference in its entirety. The films produced by hot-wall LPCVD apparatus have good electrical properties suitable for MOS transistor gate and capacitor dielectrics and other applications. However, during LPCVD processes, films are inevitably deposited on the side-wall and/or components within the chamber, which may eventually generate particles and degrade the CVD process. Thus, periodic cleaning of LPCVD apparatus is needed to remove undesired deposited films.

In the prior art, LPCVD apparatus are conventionally cleaned by wet etching. Wet etching is a time-consuming process which requires cooling and disassembling of the system, wet etching the quartzware, then re-assembling, heating and re-qualifying of the process. Moreover, wet chemical wastes such as nitric acid (HN03) and hydrogen fluoride (HF) are detrimental to the environment and disposal of the wastes is cumbersome.

Plasma-assisted nitrogen trifluoride (NF₃) cleaning has been developed in the semiconductor industry as an alternative method to wet etching cleaning techniques using hexafluoroethane (C₂F₆) and tetrafluoromethane (CF₄) which are believed to contribute to global warming problems. However, plasma-assisted NF₃ cleaning process requires installation of additional devices such as plasma generators which increase the cost of the system. Thus further development in cost-effective and environmentally benign cleaning methods for semiconductor apparatus is needed.

### SUMMARY OF THE INVENTION

Accordingly, in general, it is an object of the present invention to provide a method of cleaning semiconductor processing apparatus.

The invention provides a cost-effective and environmentally benign cleaning method, which comprises introducing one or more etch gases, preferably including at least a fluorine containing gas, into the chamber, performing a first cleaning process to remove the deposited materials at a high rate, and performing a second cleaning process to remove the deposited materials at a high selectivity with respect to the materials forming the chamber. The first cleaning process is performed at a first pressure and the second cleaning process is performed at a second pressure. The second pressure is preferably substantially lower than the first pressure. The undesired materials deposited in the chamber to be cleaned include silicon nitride, silicon oxide, silicon oxynitride, polysilicon, amorphous silicon, germanium, Ge-doped polysilicon, refractory metals, metal nitrides, metal oxynitrides, metal silicides, metal oxide, metal carbide, and metal silicates. The etch gases can be introduced into the chamber through a gas inlet or a removable quartz injector that is an integral part of the chamber.

In one embodiment, the first cleaning process is performed at a first pressure ranging from about 100 to about 700 Torr, more preferably from about 300 to about 700 Torr. The second cleaning process is performed at a pressure ranging from about 5 to about 100 Torr, more preferably from about 5 to 50 Torr.

In another embodiment, the side-wall and/or components of the chamber to be cleaned are made of quartz and the material deposited in the chamber is silicon nitride. The second cleaning process is preformed at a high etch selectivity of silicon nitride to quartz from about 2:1 to about 300:1. In a further embodiment, the material deposited in the chamber is polysilicon, and the second cleaning process is preformed at a high etch selectivity ranging of polysilicon to quartz from about 5:1 to about 2000:1.

In another embodiment of the present invention, there is provided a method of in situ cleaning of quartzware in a chemical vapor deposition chamber which have undesired materials deposited thereon. The method comprises positioning the quartzware within the chamber in a processing position substantially same as in a chemical vapor deposition (CVD), introducing a cleaning gas into the chamber at a temperature substantially the same as the CVD temperature, performing a first cleaning process at a first pressure to remove the deposited materials at a high etch rate, and performing a second cleaning process at a second pressure to remove the deposited materials at a high etch selectivity of the undesired materials to the quartzware.

### BRIEF DESCRIPTION OF THE DRAWINGS

These and other objects of the present invention will become better understood upon reading the detailed description of the invention and the appended claims provided below, and upon reference to the drawings, in which:

FIG. 1 schematically shows a low pressure hot-wall rapid thermal processing reactor according to one embodiment of the present invention.

FIG. 2 is a graph showing the function of wafer temperature versus heater setpoints at various elevator height.

FIG. 3 is a graph illustrating the effect of temperature and pressure on the etch rate of an oxide according to one embodiment of the invention where NF₃ gas is introduced by a gas inlet installed at the side-wall of the chamber.

FIG. 4 is a graph illustrating the effect of temperature and NF₃ flow rate on the etch rate of an oxide according to one embodiment of the invention where NF₃ gas is introduced by a gas inlet installed at the side-wall of the chamber.

FIG. 5 is a graph illustrating the effect of pressure and N₂ flow on the etch rate of an oxide according to one embodiment of the invention where NF3 gas is introduced by an injector.

FIG. 6 is a graph illustrating the effect of elevator height on NF3 oxide etch rate according to one embodiment of the invention where NF₃ gas is introduced by an injector.

FIG. 7 is a graph illustrating the effect of wafer temperature on the etch rate of an oxide according to one embodiment of the invention where NF₃ gas is introduced by an injector.

FIG. 8 is a graph illustrating the effect of pressure on etch rates according to one embodiment of the invention where NF₃ gas is introduced by an injector.

FIG. 9 is a graph illustrating the effect of temperature and pressure on etch rates according to one embodiment of the invention where NF₃ gas is introduced by an injector.

FIG. 10 is a graph illustrating the effect of temperature and elevator height on etch rates according to one embodiment of the invention where NF3 gas is introduced by an injector.

FIGS. 11 and 12 are graphs illustrating RGA analysis of NF₃ cleaning endpoint detection according to one embodiment of the invention.

### DETAILED DESCRIPTION OF THE INVENTION

FIG. 1 schematically shows a low pressure hot-wall rapid thermal processing (RTP) reactor 10 that may be used to carry out the process according to one embodiment of the present invention. The hot-wall RTP reactor 10 generally comprises a chamber 14 into which a single substrate 20 is loaded. The wall of the chamber 14 is preferably made of quartz. A plurality of heating elements 12 are provided adjacent to the upper end of the chamber 14. Suitable heating elements 12 include resistive heating elements coupled with a power source controlled by a computer (not shown). An isothermal plate 13, preferably made of silicon carbide, is disposed inside and adjacent to the upper end of the chamber 14. The heating elements 12 and isothermal plate 13 serve as heating sources for the use of the RTP reactor 10. The isothermal plate 13 can be placed within the chamber 14 or on the top of chamber 14. The isothermal plate 13 receives heat rays radiated from the heating elements 12 and radiates secondary heat rays into the chamber 14. The isothermal plate 13 can produce a more uniform thermal distribution on the surface of the substrate 20.

The hot-wall RTP reactor 10 further comprises one or more insulation sidewalls 24 adjacent to the sidewall of chamber 14. Heating means (not shown) are provided between the insulation sidewalls 24 and the sidewall of the chamber 14 to heat the sidewall of the chamber 14 to achieve a more accurate control over the temperature within the chamber 14.

The substrate 20 is supported by a platform 22 which is coupled with an elevator 26 for moving the substrate 20 into and out of the chamber 14. One or more gas inlets 16 can be disposed at the sidewall of the chamber 14 and connected to one or more gas manifolds (not shown) which convey a gas or a mixture of gases into the chamber 14. The gas concentration and flow rates through each of the gas inlets 16 are selected to produce gas flows and concentration that optimize processing uniformity. An exhaust line 18 is provided at the sidewall of the chamber 14 opposite the gas inlets 16 and connected to a pump 28 for exhausting the chamber 14.

In another embodiment, a removable injector 16 as shown in FIG. 1 is provided as an integral part within the chamber to introduce a gas or a mixture of gases. The removable injector is preferably made of quartz. The injector can deliver the gas flow to the center of the chamber and thus enhance processing uniformity. U.S. Pat. No. 6,300,600, entitled “Hot Wall Rapid Thermal Processor” describes the structure and installation of an injector suitable for use with the present invention, the entire disclosure of which is incorporated hereby by reference. The injector can be installed at an angle of 20 degree relative to the downward vertical position. Alternatively, the injector can be installed in a downward vertical position in conjunction with a quartz baffle plate (not shown). The quartz baffle plate has a hole in the center large enough for the injector to poke through. While one specific hot-wall RTP reactor has been described, the present invention is in no way limited to this specific design, and other hot-wall reactors may be employed in the present invention. The present method can also be used to clean batch furnaces.

In one aspect of the present invention, there is provided a method of cleaning a hot-wall RTP reactor 10 having undesired materials deposited on the quartz side wall of the chamber, quartz waffle plate, or other quartzware components within the chamber including but not limited to the wafer carrier, spokes, rods, and the like. The undesired deposited materials include, but are not limited to silicon nitride, silicon oxide, silicon oxynitride, silicon carbide, polysilicon, amorphous silicon, germanium, Ge-doped polysilicon, refractory metals (such as: W, Mo, Ta), metal nitrides (such as: TiN, TaN), metal oxynitrides (such as; TaOₓN_{y}, ZrOₓN_{y}, HfOₓN_{y}), metal silicides (such as: WSi, TiSi), metal oxide (such as:Ta₂O₅, ZrO₂, HfO₂), metal carbide (such as: WC, TiC), and metal silicates (such as: Zr—Si—O, Hf—Si—O).

In one embodiment, the present cleaning method comprises use of a thermal reaction of NF₃ gas with the undesired deposited materials. The NF₃ gas can be introduced into the chamber to be cleaned by a gas inlet or removable injector that is used to introduce CVD processing gas. In one embodiment, the cleaning gas is pure NF₃ gas. Alternatively, NF₃ gas can be diluted with oxygen, one or more inert gases, or a mixture of both oxygen and one or more inert gases. Suitable inert gases include nitrogen, argon, helium, or any mixture thereof.

The present method comprises a first cleaning process at a first pressure to remove the deposited materials at a high etch rate, and a second cleaning process at a second pressure to remove the deposited materials at a high etch selectivity with respect to the quartzware. To enhance cleaning efficiency, the first cleaning process can be conducted at a relative high pressure and a temperature substantially same as or below a typical CVD process temperature for deposition of silicon nitride, oxide, oxynitride and polysilicon, etc. Preferably the first cleaning process is conducted at a temperature ranging from about 500 to 800° C., and at a pressure ranging from about 100 to 700 Torr, more preferably at a pressure ranging from about 300 to 700 Torr, and most preferably at a pressure ranging from about 350 to 700 Torr. The high etch rate of the first cleaning process can reach up to approximately 15 μm/min. Preferably the etch rate of the first cleaning process ranges from about 5 to 10 μm/min.

The thermal reaction of the deposited materials with NF₃ gas generates volatile silicon containing gases, which are then exhausted from the chamber through pipe line 18. For example, the thermal reaction that removes silicon nitride deposits is as follows:

Si₃N₄+4 NF₃o 3SiF₄+4N₂

The thermal dissociation of NF₃ generates reactive fluorine atoms. The fluorine atoms etch silicon containing deposits such as Si and SiNₓ to form volatile silicon tetrafluoride (SiF₄), which is exhausted from the chamber through pipe line 18.

As the first cleaning process reaches the endpoint, the second cleaning process is conducted to remove the unwanted deposited material at a high etch selectivity to protect the chamber quartzware from being etched. In other words, the unwanted deposited materials are etched at a faster rate than the quartzware or silicon oxide. The endpoint of the first cleaning process is monitored using a residual gas analysis (RGA) system known in the art by tracking levels of various gases. The second cleaning process is preferably conducted at a pressure substantially lower than the first pressure of the first cleaning process. Preferably the second pressure ranges from about 5 to 100 Torr, more preferably from about 5 to 75 Torr, and most preferably from about 5 to 50 Torr. A high etch selectivity of more than 100:1 in etching silicon nitride against silicon oxide, and a high selectivity of more than 1000:1 in etching polisilicon against silicon oxide are achieved according to the present cleaning method. Preferably the etch selectivity of nitride respect to oxide ranges from about 2:1 to 300:1. The etch selectivity of polysilicon with respect to oxide preferably ranges from about 5:1 to 2000:1.

In another embodiment of the present invention, there is provided a method for in situ cleaning wafer carrier components such as wafer platform, spokes and rod etc. in a CVD chamber. The method comprises positioning the components within the chamber in a height substantially the same as during chemical vapor deposition processing and introducing a NF₃ containing gas into the chamber at a temperature substantially the same during chemical vapor deposition processing to perform a first cleaning process to remove the deposited materials at a high etch rate. Then a second cleaning process is performed to remove the deposited materials with a high etch selectivity with respect to the wafer carrier components. The pressure in the second cleaning process is preferably substantially lower than the pressure of the first cleaning process to enhance the etch selectivity. The temperature of the second cleaning process can be same as the temperature of the first cleaning process, or the same as the temperature of the CVD process. However, the temperature of the second cleaning process can be lower than the first cleaning process to enhance the etch selectivity for removing the undesired material at a higher rate respect to the wafer carrier components. In particular, the first cleaning process is preferably performed at a temperature ranging from about 500 to 800° C., and at a pressure ranging from 100 to 700 Torr, more preferably from about 300 to 700 Torr, and most preferably from about 350 to 700 Torr. The second cleaning process is preferably conducted at a temperature ranging from about 500 to 800° C., and at a pressure ranging from about 5 to 100 Torr, more preferably from about 5 to 75 Torr, and most preferably from about 5 to 50 Torr.

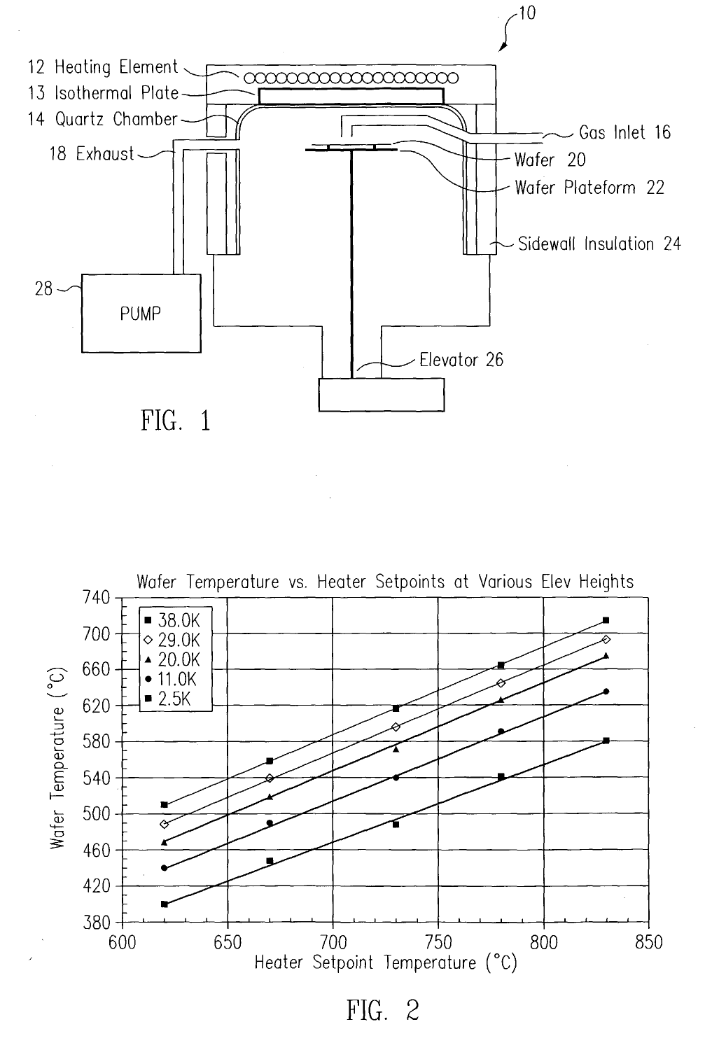

The following examples are provided to illustrate the system and method of the present invention, and are not intended to limit the scope of the invention in any way. In the examples, wafers with silicon nitride films having a thickness of approximate 1.0 micron were prepared as filler wafers. Wafers with polysilicon films having a thickness of about 3500A on a 500A oxide underlayer were also prepared. Thermal oxide films having a thickness of approximate 1.0 micron were generated using a wet oxide process in a horizontal furnace available from ASML US, Inc. in Scott Valley, Calif. NF₃ was used as the cleaning gas. Thermal couple (TC) wafers were used to measure wafer temperatures at various elevator heights throughout the process chamber, as illustrated in FIG. 2. The etch rates were derived from the decrease in film thickness on the wafers placed on the wafer platform in the chamber under the NF₃ gas flow. The film thickness was measured by Ellipsometry.

### EXAMPLE 1

This example illustrates one embodiment of the present cleaning method by introducing NF₃ gas through a gas inlet installed at the side-wall of the chamber to be cleaned.

A series of tests were run under various temperature, pressure, and NF3 flow rate conditions to determine the effects on the oxide etch rate. The test conditions and results are summarized in Table 1.

TABLE 1

| | | | | | | | Oxide | | |
|---|---|---|---|---|---|---|---|---|---|
| | Setpt | Wfr | Elev Ht | NF3 | Max Pres | Etch Time | Pre-Cln | Post-Cln | Etch rate |
| Run # | Temp | Temp | (k cts) | (slm) | (Torr) | (min) | Thick (Å) | Thick (Å) | (A/min) |
| 1680 | 830 | 710 | 28.0 | 4.0 | 175.6 | 2.00 | 8209.3 | 7906.3 | 151.5 |
| 1681 | 830 | 710 | 28.0 | 4.0 | 184.0 | 2.00 | | | 0.0 |
| 1682 | 830 | 710 | 40.0 | 4.0 | 204.0 | 2.00 | | | 0.0 |
| 1683 | 830 | 710 | 40.0 | 4.0 | 203.0 | 2.00 | | | 0.0 |
| 1684 | 830 | 710 | 40.0 | 1.0 | 46.6 | 2.00 | | | 0.0 |
| 1685 | 830 | 710 | 40.0 | 1.0 | 41.8 | 10.00 | | | 0.0 |
| 1686 | 830 | 710 | 40.0 | 4.0 | 300.0 | 10.00 | | | 0.0 |
| 1687 | 830 | 710 | 40.0 | 4.0 | 113.0 | 2.00 | 8194.5 | 7465.8 | 364.4 |
| 1688 | 830 | 710 | 40.0 | 4.0 | 220.0 | 2.00 | 8190.7 | 4731.4 | 1729.7 |
| 1689 | 830 | 710 | 40.0 | 4.0 | 199.0 | 2.00 | 8180.7 | 7659.0 | 260.9 |
| 1690 | 830 | 710 | 40.0 | 4.0 | 10.0 | 2.00 | 8174.0 | 6744.3 | 714.9 |
| 1691 | 830 | 710 | 40.0 | 4.0 | 50.0 | 2.00 | 8183.2 | 3566.0 | 2308.6 |
| 1692 | 830 | 710 | 40.0 | 4.0 | 30.0 | 2.00 | 8198.5 | 6854.4 | 672.1 |
| 1693 | 830 | 710 | 40.0 | 4.0 | 20.0 | 1.00 | 8201.2 | 1956.0 | 6245.2 |
| 1694 | 830 | 710 | 40.0 | 1.0 | 10.0 | 1.00 | 8204.0 | 553.9 | 7650.1 |
| 1695 | 830 | 710 | 40.0 | 4.0 | 10.0 | 1.00 | 8218.3 | 3948.5 | 4269.8 |
| 1696 | 830 | 710 | 40.0 | 1.0 | 10.0 | 1.00 | | | 0.0 |
| 1697 | 830 | 710 | 40.0 | 1.0 | 10.0 | 1.00 | | | 0.0 |
| 1698 | 830 | 710 | 40.0 | 1.0 | 2.5 | 0.50 | 8222.4 | 7509.8 | 1425.2 |
| 1699 | 670 | 550 | 40.0 | 1.0 | 10.0 | 1.00 | 8229.8 | 8230.9 | −1.1 |
| 1700 | 670 | 550 | 40.0 | 4.0 | 10.0 | 1.00 | 8222.2 | 8210.4 | 11.8 |
| 1701 | 670 | 550 | 40.0 | 4.0 | 50.0 | 2.00 | 8223.3 | 8206.2 | 8.5 |
| 1702 | 750 | 630 | 40.0 | 4.0 | 50.0 | 2.00 | 8234.3 | 8048.7 | 92.8 |
| 1703 | 750 | 630 | 40.0 | 4.0 | 10.0 | 1.00 | 8240.2 | 7839.1 | 401.1 |
| 1704 | 750 | 630 | 40.0 | 1.0 | 10.0 | 1.00 | 8236.1 | 5324.0 | 2912.1 |
| 1705 | 750 | 630 | 40.0 | 1.0 | 5.0 | 1.00 | 8234.2 | 6813.2 | 1421.0 |
| 1706 | 750 | 630 | 40.0 | 1.0 | 10.0 | 1.00 | | | 0.0 |
| 1707 | 830 | 710 | 40.0 | 1.0 | 10.0 | 1.00 | | | 0.0 |
| 1708 | 830 | 710 | 40.0 | 1.0 | 10.0 | 0.75 | | | 0.0 |
| 1709 | 830 | 710 | 40.0 | 1.0 | 10.0 | 1.50 | | | 0.0 |
| 1710 | 830 | 710 | 40.0 | 1.0 | 10.0 | 0.50 | | | 0.0 |
| 1711 | 830 | 710 | 40.0 | 1.0 | 10.0 | 1.00 | | | 0.0 |
| 1712 | 750 | 630 | 40.0 | 1.0 | 10.0 | 1.00 | | | 0.0 |

| | Nitride | | | PolySi | | |
|---|---|---|---|---|---|---|
| | Pre-Cln | Post-Cln | Etch rate | Pre-Cln | Post-Cln | Etch rate |
| Run # | Thick (Å) | Thick (Å) | (A/min) | Thick (Å) | Thick (Å) | (A/min) |
| 1680 | | | 0.0 | | | 0.0 |
| 1681 | 9644.0 | | | | | 0.0 |
| 1682 | 9663.2 | | | | | 0.0 |
| 1683 | | | 0.0 | 3260.9 | 2599.9 | 330.5 |
| 1684 | | | 0.0 | 3154.6 | 2998.9 | 77.8 |
| 1685 | | | 0.0 | 3297.1 | 2973.0 | 32.4 |
| 1686 | | | 0.0 | 3313.2 | 3080.7 | 23.3 |
| 1687 | | | 0.0 | | | 0.0 |
| 1688 | | | 0.0 | | | 0.0 |
| 1689 | | | 0.0 | | | 0.0 |
| 1690 | | | 0.0 | | | 0.0 |
| 1691 | | | 0.0 | | | 0.0 |
| 1692 | | | 0.0 | | | 0.0 |
| 1693 | | | 0.0 | | | 0.0 |
| 1694 | | | 0.0 | | | 0.0 |
| 1695 | | | 0.0 | | | 0.0 |
| 1696 | | | 0.0 | 3278.6 | 2687.2 | 591.4 |
| 1697 | | | | | | 0.0 |
| 1698 | | | 0.0 | | | 0.0 |
| 1699 | | | 0.0 | | | 0.0 |
| 1700 | | | 0.0 | | | 0.0 |
| 1701 | | | 0.0 | | | 0.0 |
| 1702 | | | 0.0 | | | 0.0 |
| 1703 | | | 0.0 | | | 0.0 |
| 1704 | | | 0.0 | | | 0.0 |
| 1705 | | | 0.0 | | | 0.0 |
| 1706 | | | 0.0 | 3400.2 | 2964.7 | 435.5 |
| 1707 | | | 0.0 | 3337.8 | 0.0 | 3337.8 |
| 1708 | | | 0.0 | | 971.4 | −1295.2 |
| 1709 | | | 0.0 | | 757.3 | −1514.6 |
| 1710 | 1878.8 | 1083.8 | 1590.0 | | | 0.0 |
| 1711 | 1906.4 | 649.1 | 1257.3 | | | 0.0 |
| 1712 | 1888.7 | 1035.0 | 853.7 | | | 0.0 |

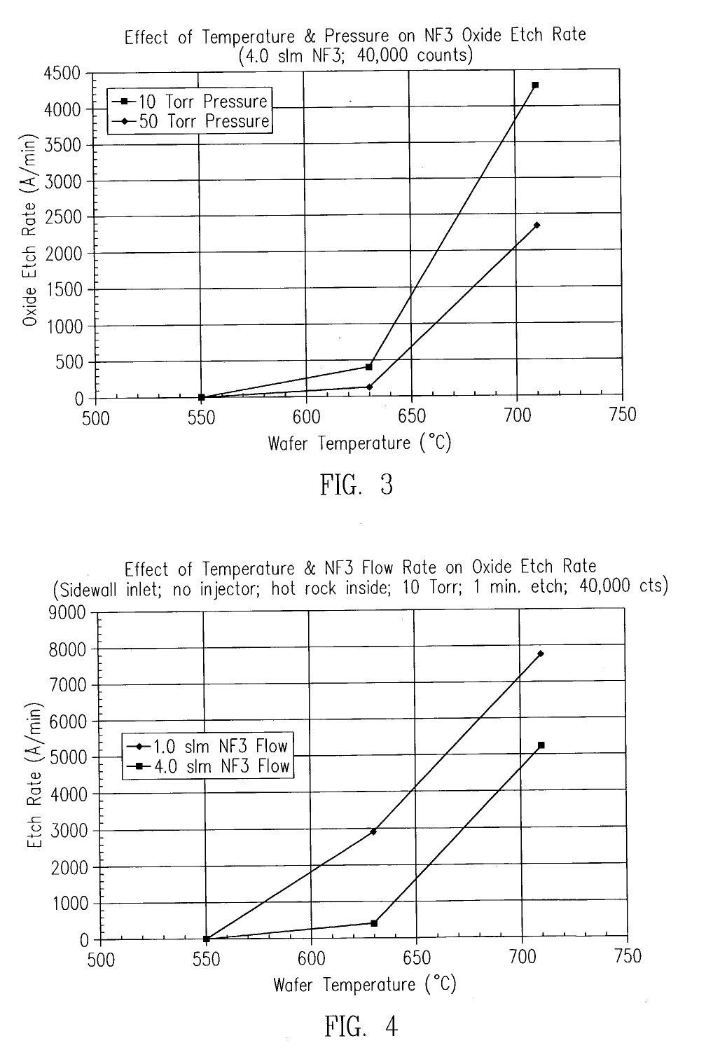

FIGS. 3 and 4 illustrate the effect of temperature, pressure, and NF₃ flow rate on the oxide etch rate. As indicated in FIG. 3, at NF₃ flow rate of 4.0 slm and wafer height of 40.0K counts, the oxide etch rate increases significantly as the wafer temperature increases. As used herein 4000 counts is equivalent to one inch in height. As indicated in FIG. 4, lower pressures (10 Torr) and lower NF3 flow rates (1 slm) are more effective in removing oxide layers. This unexpected result may be due to a high degree of directionality to the gas flow at higher pressures and flows, yielding poor gas dispersion over the surface of the wafer. Oxide etch rates were also much more uniform under the optimum conditions for etch selectivity.

### EXAMPLE 2

This example illustrates another embodiment of the present cleaning method by introducing NF₃ gas through an injector as an integral part of the RTP reactor.

The injector was installed in two variations. In the first variation, the injector was installed at an angle of 20 degree from a vertical position which was the same configuration used for optimum high deposition rate of 2% SiH₄/NH₃ nitride performance. In the second variation, the straight-wall injector was installed in a downward vertical orientation using a quartz baffle plate as described above. The two variations provided substantially the same performance regarding the cleaning effect when the NF₃ flow rates, temperatures, and pressures were determined.

NF₃ gas was introduced to the evacuated chamber at a designed flow rate for a standard etch time of one minute to achieve etch rate pressure. The pressure reached at the end of this time period was recorded as the process pressure. The test conditions including temperatures, pressures, NF3 flow rates, and etch time, and cleaning results for oxide, nitride, and polysilicon films are summarized in Table 2.

TABLE 2

| | | | | | | | Etch | Oxide | | |
|---|---|---|---|---|---|---|---|---|---|---|
| | Setpt | Wfr | Et Ht | NF3 | N2 | Max Pres | Time | PreCln | PostCln | EtchRate |
| Run # | Tm | Tm | k cts | (slm) | (slm) | (Torr) | (min) | Th(Å) | Th(Å) | (A/min) |

Injector configuration 20 degree injector angle; SiC carrier plate installed.

| | | | | | | | | | |
|---|---|---|---|---|---|---|---|---|---|
| 1744 | 842 | 720 | 38.0 | 1.0 | 10.0 | 1.00 | 8239.2 | 7738.3 | 500.9 |
| 1745 | 842 | 720 | 38.0 | 3.0 | 10.0 | 1.00 | 8263.2 | 7821.0 | 442.2 |
| 1746 | 842 | 720 | 38.0 | 3.0 | 50.0 | 1.00 | 8210.8 | 6863.9 | 1346.9 |
| 1747 | 842 | 720 | 38.0 | 1.0 | 50.0 | 1.00 | 8190.8 | 7365.0 | 825.8 |
| 1748 | 842 | 720 | 38.0 | 4.0 | 95.0 | 1.00 | 8178.7 | 4562.9 | 3615.8 |

Injector configuration 20 degree injector angle; SiC carrier plate installed.

| | | | | | | | | | | |
|---|---|---|---|---|---|---|---|---|---|---|
| 1781 | 830 | 710 | 38.0 | 1.0 | | 10.0 | 1.00 | 8101.8 | 7686.9 | 414.9 |
| 1782 | 830 | 710 | 38.0 | 3.0 | | 10.0 | 1.00 | 8490.8 | 8178.5 | 312.3 |
| 1783 | 830 | 710 | 38.0 | 3.0 | | 50.0 | 1.00 | 10039.8 | 8727.3 | 1312.5 |
| 1784 | 830 | 710 | 38.0 | 1.0 | | 50.0 | 1.00 | 10041.0 | 9219.8 | 821.2 |
| 1785 | 830 | 710 | 38.0 | 4.0 | | 95.0 | 1.00 | 10005.7 | 8310.7 | 1695.0 |
| 1786 | 830 | 710 | 36.0 | 4.0 | | 95.0 | 1.00 | 10008.4 | 8534.1 | 1474.3 |
| 1787 | 830 | 710 | 38.0 | 4.0 | | 95.0 | 1.00 | 9984.6 | 6598.2 | 3386.3 |
| 1793 | 830 | 710 | 2.5 | 4.0 | | 95.0 | 1.00 | 9986.2 | 9963.4 | 22.8 |
| 1794 | 830 | 710 | 38.0 | 4.0 | 2.0 | 95.0 | 1.00 | 10008.9 | 7892.3 | 2116.6 |
| 1795 | 830 | 710 | 38.0 | 4.0 | | 95.0 | 0.17 | | | |
| 1796 | 830 | 710 | 38.0 | 4.0 | | 95.0 | 0.08 | | | |
| 1797 | 830 | 710 | 38.0 | 4.0 | | 95.0 | 0.08 | | | |
| 1798 | 830 | 710 | 38.0 | 4.0 | | 95.0 | 0.17 | 9963.4 | 9017.4 | 5676.1 |
| 1799 | 830 | 710 | 29.0 | 4.0 | | 95.0 | 0.17 | 10012.6 | 9728.0 | 1707.4 |
| 1800 | 830 | 710 | 20.0 | 4.0 | | 95.0 | 0.17 | 9980.1 | 9844.5 | 813.5 |
| 1801 | 830 | 710 | 11.0 | 4.0 | | 95.0 | 0.17 | 10006.0 | 9944.6 | 368.4 |
| 1802 | 780 | 660 | 38.0 | 4.0 | | 95.0 | 0.17 | 9966.3 | 9811.2 | 930.4 |
| 1803 | 780 | 660 | 38.0 | 4.0 | | 95.0 | 0.08 | | | |
| 1804 | 780 | 660 | 38.0 | 4.0 | | 95.0 | 0.08 | | | |
| 1805 | 730 | 610 | 38.0 | 4.0 | | 95.0 | 0.17 | 9968.5 | 9906.2 | 373.8 |
| 1806 | 730 | 610 | 38.0 | 4.0 | | 95.0 | 0.08 | | | |
| 1807 | 730 | 610 | 38.0 | 4.0 | | 95.0 | 0.08 | | | |
| 1808 | 780 | 660 | 38.0 | 4.0 | | 95.0 | 0.08 | | | |
| 1809 | 780 | 660 | 38.0 | 4.0 | | 95.0 | 0.08 | | | |
| 1810 | 830 | 710 | 2.5 | 4.0 | | 95.0 | 0.08 | | | |
| 1811 | 830 | 710 | 2.5 | 4.0 | | 95.0 | 0.08 | | | |
| 1812 | 830 | 710 | 38.0 | 4.0 | | 95.0 | 0.42 | 9976.3 | 8549.7 | 3423.8 |
| 1813 | 830 | 710 | 38.0 | 4.0 | | 95.0 | 0.67 | 9968.6 | 7984.1 | 2976.8 |
| 1814 | 830 | 710 | 38.0 | 4.0 | | 95.0 | 1.00 | 9961.0 | 7370.7 | 2590.3 |
| 1816 | 670 | 550 | 38.0 | 4.0 | | 75.0 | 0.17 | 9956.0 | 9956.0 | 0.0 |
| 1817 | 670 | 550 | 38.0 | 4.0 | | 75.0 | 0.08 | | | |
| 1818 | 670 | 550 | 38.0 | 4.0 | | 75.0 | 0.08 | | | |

Control chamber pressure to 350 Torr using second PC_On step at 15 slm N2 flow prior to NF3
(instead of rising to pressure under NF3 flow only). Manually closing gas

| | | | | | | | | | |
|---|---|---|---|---|---|---|---|---|---|
| 1819 | 670 | 550 | 38.0 | 4.0 | 387.0 | 0.08 | | | |
| 1820 | 670 | 550 | 38.0 | 4.0 | 373.0 | 0.08 | | | |
| 1821 | 670 | 550 | 38.0 | 4.0 | 374.0 | 1.00 | 9964.1 | 9933.7 | 30.4 |
| 1822 | 670 | 550 | 2.5 | 4.0 | 364.0 | 0.08 | | | |
| 1823 | 670 | 550 | 2.5 | 4.0 | 369.0 | 0.08 | | | |
| 1824 | 780 | 660 | 2.5 | 4.0 | 370.0 | 0.08 | | | |
| 1825 | 780 | 660 | 2.5 | 4.0 | 390.0 | 0.08 | | | |
| 1826 | 780 | 660 | 38.0 | 4.0 | 400.0 | 0.08 | | | |
| 1827 | 780 | 660 | 38.0 | 4.0 | 400.0 | 0.17 | 9933.7 | 9222.2 | 4269.1 |
| 1828 | 780 | 660 | 2.5 | 4.0 | 372.0 | 0.17 | 9961.1 | 9949.1 | 71.8 |
| 1829 | 780 | 660 | 2.5 | 4.0 | 367.0 | 0.08 | | | |
| 1830 | 780 | 660 | 38.0 | 4.0 | 382.0 | 0.08 | | | |

| | Nitride | | | PolySi | | |
|---|---|---|---|---|---|---|
| | PrCln | PoCln | EtchRate | PrCln | PoCln | EtchRate |
| Run # | Th(Å) | Th(Å) | (A/min) | Th(Å) | Th(Å) | (A/min) |
| Injector configuration 20 degree injector angle; | | | | | | |
| SiC carrier plate installed. | | | | | | |
| 1744 | | | | | | |
| 1745 | | | | | | |
| 1746 | | | | | | |
| 1747 | | | | | | |
| 1748 | | | | | | |
| Injector configuration 20 degree injector angle; | | | | | | |
| SiC carrier plate installed. | | | | | | |
| 1781 | | | | | | |
| 1782 | | | | | | |
| 1783 | | | | | | |
| 1784 | | | | | | |
| 1785 | | | | | | |
| 1786 | | | | | | |
| 1787 | | | | | | |
| 1793 | | | | | | |
| 1794 | | | | | | |
| 1795 | 1013.6 | 0.0 | 6081.4 | | | |
| 1796 | 966.9 | 92.6 | 10492.1 | | | |
| 1797 | | | | 3385.2 | −400.0 | 45422.4 |
| 1798 | | | | | | |
| 1799 | | | | | | |
| 1800 | | | | | | |
| 1801 | | | | | | |
| 1802 | | | | | | |
| 1803 | 1023.2 | 120.8 | 11279.5 | | | |
| 1804 | | | | 3385.0 | −163.0 | 42576.0 |
| 1805 | | | | | | |
| 1806 | 930.3 | 654.8 | 3305.4 | | | |
| 1807 | | | | 3397.4 | 49.9 | 40170.3 |
| 1808 | 1007.8 | 214.9 | 9513.9 | | | |
| 1809 | | | | 3391.2 | −142.0 | 42398.9 |
| 1810 | 876.2 | 652.5 | 2685.0 | | | |
| 1811 | | | | 3337.0 | 219.0 | 37416.1 |
| 1812 | | | | | | |
| 1813 | | | | | | |
| 1814 | | | | | | |
| 1816 | | | | | | |
| 1817 | 951.4 | 878.4 | 876.4 | | | |
| 1818 | | | | 3332.3 | 2857.0 | 5703.5 |

Control chamber pressure to 350 Torr using second PCOn step at 15 slm
N2 flow prior to NF3 (instead of rising to pressure under NF3 flow
only). Manually closing gas

| | | | | | | |
|---|---|---|---|---|---|---|
| 1819 | | | | 3396.4 | 282.0 | 37372.7 |
| 1820 | 1068.1 | 804.3 | 3165.3 | | | |
| 1821 | | | | | | |
| 1822 | 3381.6 | 3373.3 | 99.5 | | | |
| 1823 | 801.2 | 798.5 | 32.7 | | | |
| 1824 | | | | 3373.3 | 2997.8 | 4507.0 |
| 1825 | 759.4 | 528.4 | 2771.6 | | | |
| 1826 | 940.6 | 5.7 | 11219.2 | | | |
| 1827 | | | | | | |
| 1828 | | | | | | |
| 1829 | 821.7 | 671.2 | 1805.6 | | | |
| 1830 | 1128.6 | 1.7 | 13523.3 | | | |

### EXAMPLE 3

A silicon carbide disc 0.1143 cm thick, with an outside diameter of 9.5072 cm and a hole in the center diameter of 2.6835 cm, with a mass of 25.0254 g was cut into quarters and used for etch rate testing. For the test, one of the SiC quarters had a pre-etch mass of 5.9350 g. This sample was placed on a 200 mm wafer for seven successive five minute NF₃ etch cycles for a total etch time of 35 minutes. Etching was performed at a temperature of 750° C., and at a pressure of 45 Torr using 1.65 slm NF₃ plus 2.35 slm N₂. The mass of the etched SiC sample was 5.7411 g. Using the density of the original uncut SiC sample (3.2172 g/cm³), the area of the quartered etch sample was determined to be 16.143 cm², yielding an etch rate for SiC of 1.07 μm/min.

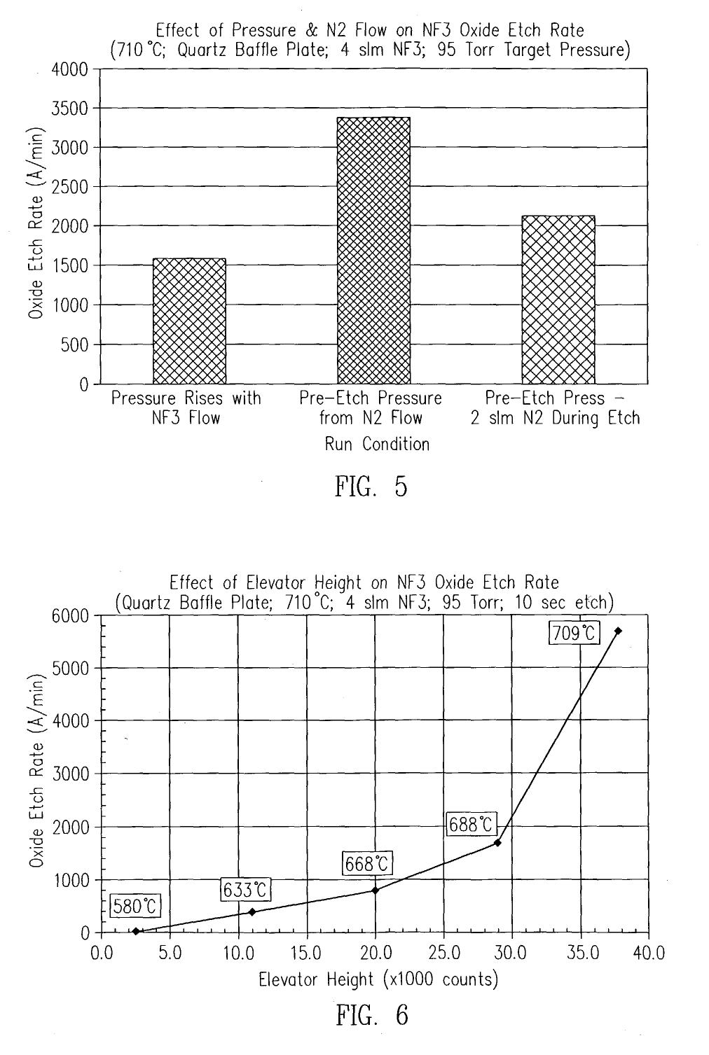

FIG. 5 shows the effect of pressure and nitrogen (N₂) flow rate on NF₃ oxide etch rate. As indicated in FIG. 5, at temperature of 71° C. and process pressure of 95 Torr, etch rates are higher when the chamber pressure is first adjusted using N₂ flow and then introducing NF₃. However, using a N₂ flow rate of 2 slm during cleaning process in order to maintain 95 Torr process pressure actually decreases oxide etch rate.

FIG. 6 shows the effect of the elevator height on oxide etch rate. As indicated in FIG. 6, at temperature of 710° C., pressure of 95 Torr, and NF₃ flow rate of 4 slm, the oxide etch rate increases as the elevator height changes from the minimum height for safe rotation (2.5K counts) at the bottom of the chamber to standard process position of 38.0K counts.

FIG. 7 shows the effect of wafer temperature on NF₃ etch rate. As indicated in FIG. 7, at a process pressure of 95 Torr, NF₃ flow rate of 4 slm, and elevator height of 38.0K counts, the oxide etch rate decreases significantly as the temperature decreases from 710 to 660° C., and is negligible at 550° C. At a temperature of 610° C., the polysilicon film of about 3400 A thickness is completely etched in 5 seconds, and at a temperature of 660° C., the nitride film of about 1000A is completely etched in 5 seconds.

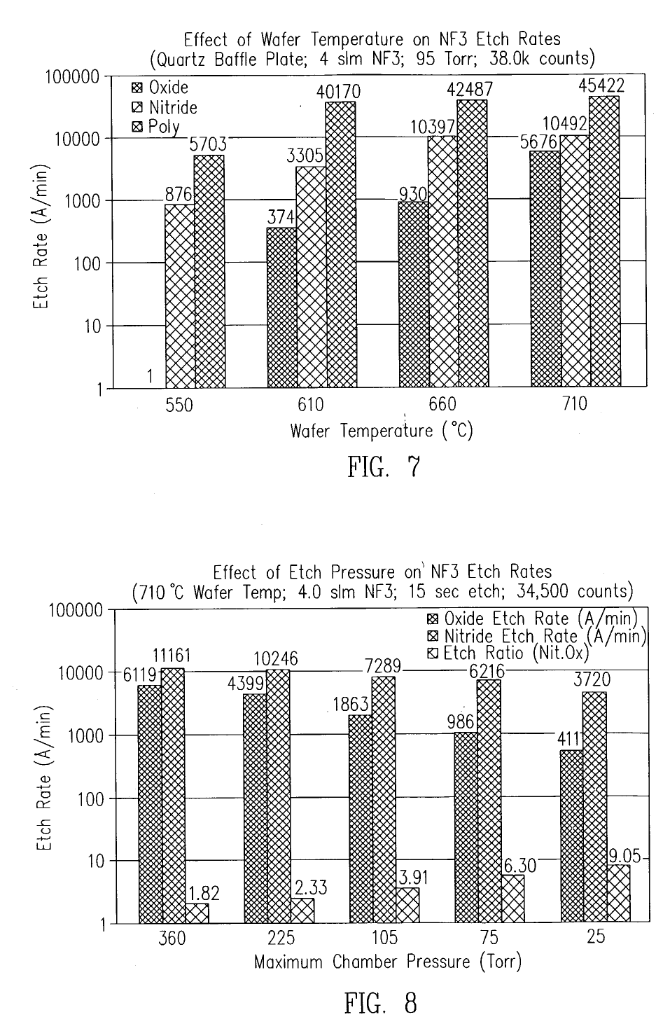

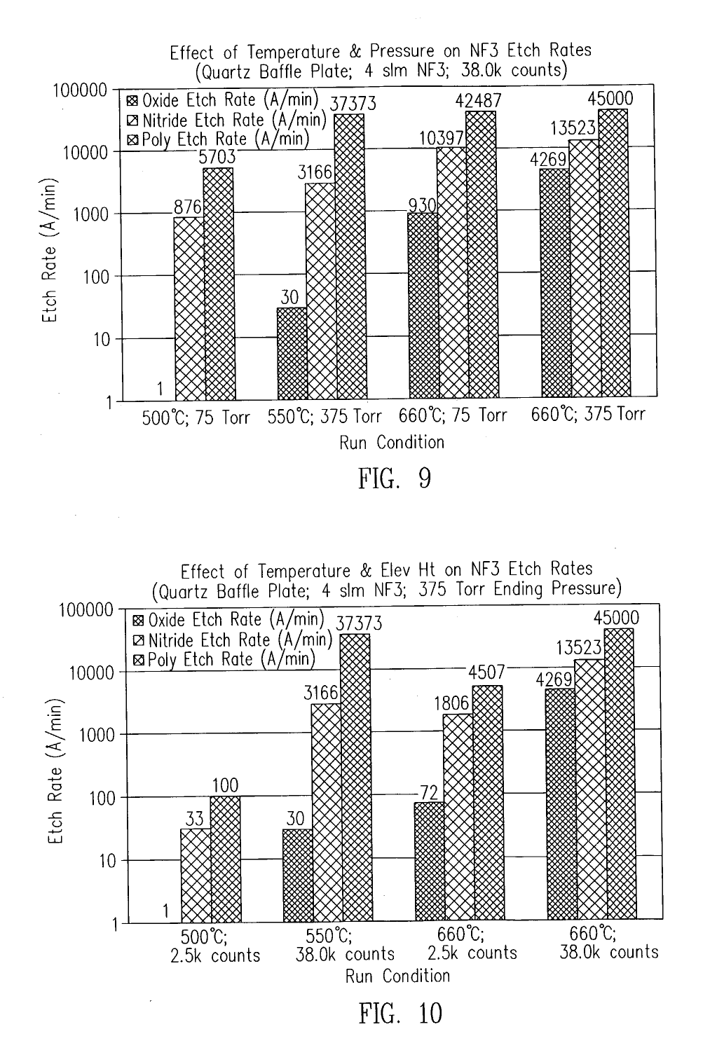

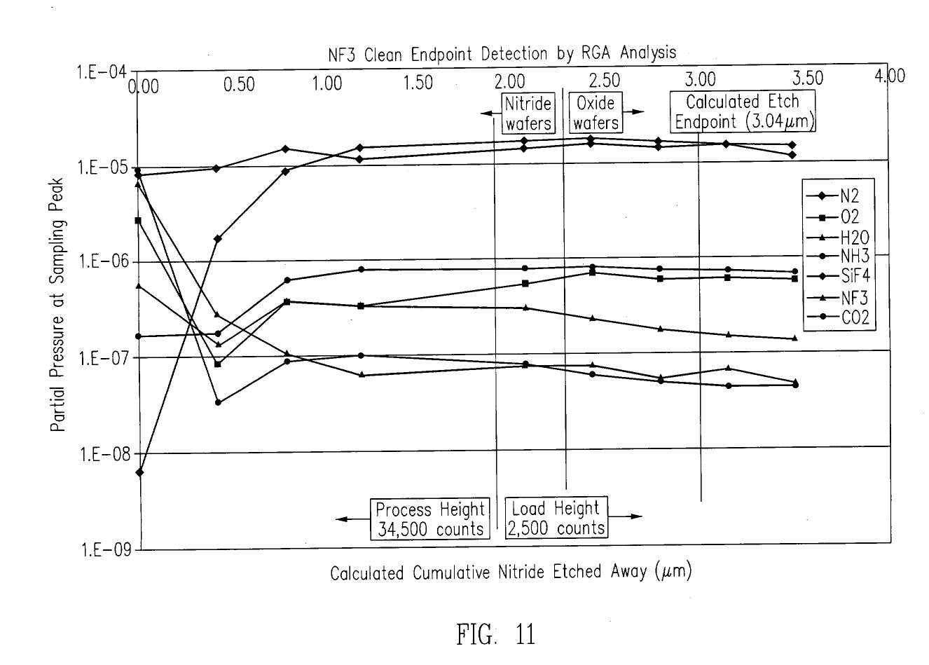

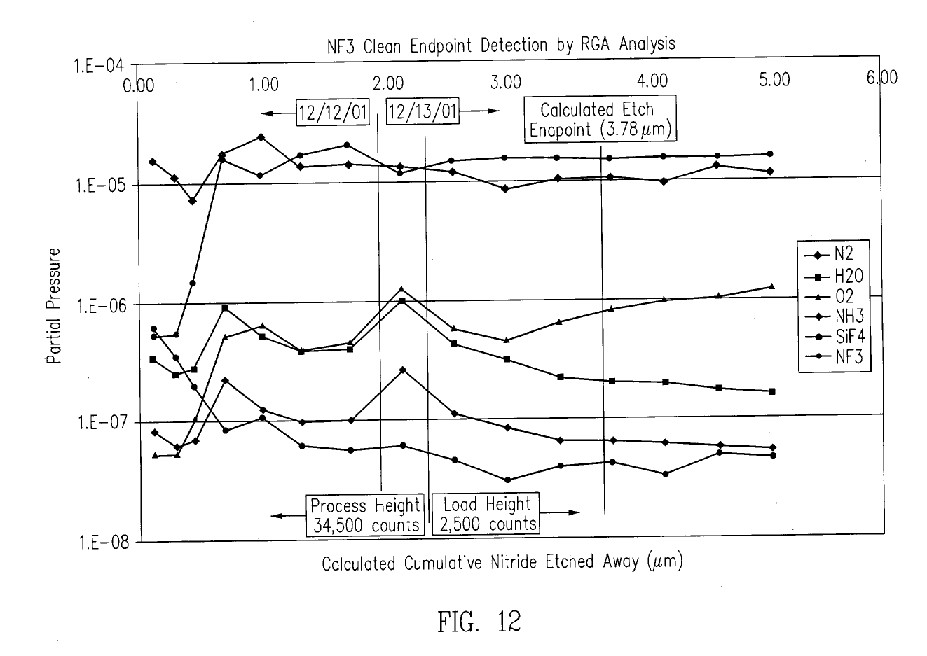

FIG. 8 shows the effect of process pressure on NF₃ etch rates. As indicated in FIG. 8, at a wafer temperature of 710° C., NF₃ flow rate of 4.0 slm, and elevator height of 34.5K counts, the etch ratio or selectivity of nitride with respect to oxide increases as the maximum chamber pressure decreases.

FIG. 9 shows the effect of temperature and pressure on NF₃ etch rates. As indicated in FIG. 9, at NF₃ flow rate of 4 slm, and elevator height of 38K counts, the oxide etch rate at temperature of 550° C. and pressure of 75 Torr is negligible. At temperature of 550° C. and pressure of 375 Torr, the oxide etch rate becomes measurable, at 30 A/min. Similarly, at temperature of 550° C., when the pressure is increased from 75 Torr to 375 Torr, the nitride etch rate is increased by a factor of 3.5, and the polysilicon etch rate is enhanced 6.5 times. The selectivity of nitride etch rate relative to oxide is then more than 100:1, and the selectivity of polysilicon etch rate relative to oxide is more than 1000:1 respectively.

FIG. 10 shows the effect of temperature and elevator height on NF₃ etch rates. As indicated in FIG. 10, at pressure of 375 Torr and NF₃ flow rate of 4 slm, for the same heater setpoints that yield a 550° C. wafer temperature at elevator height of 38.0K counts, there is still some etching of nitride and polysilicon films that occurs at the load height where the actual temperature is about 450° C. according to FIG. 2.

One advantage of the present invention is that the cleaning method can be conducted in situ using NF₃ gas without the need of a tedious process of cooling and disassembling of the system, wet etching, then re-assembling, heating and re-qualifying of the process. Moreover, the effluent gas such as SiF₄ exhausting from the reactor can be easily abated using conventional scrubbers, as in contrast to the prior art wet cleaning method which produces wet chemical waste such as HNO₃ and HF, the disposal of which is cumbersome. Another advantage of the present invention is that the cleaning method using thermal NF₃ reaction with deposited films does not require installation of additional apparatus such as plasma generators as in prior art plasma-assisted NF₃ cleaning, and thus reducing the cost of cleaning process. Moreover, the present cleaning method comprises two steps. In the first step where etching selectivity is not needed the cleaning process can be conducted at a higher pressure and temperature to enhance cleaning efficiency. In the second step where etch selectivity is needed, conditions are selected to promote the etch selectivity thereby protecting the chamber from being etched while still maintaining acceptable high etch rate.

The foregoing description of specific embodiments and examples of the invention have been presented for the purpose of illustration and description, and although the invention has been illustrated by certain of the preceding examples, it is not to be construed as being limited thereby. They are not intended to be exhaustive or to limit the invention to the precise forms disclosed, and obviously many modifications, embodiments, and variations are possible in light of the above teaching. It is intended that the scope of the invention encompass the generic area as herein disclosed, and by the claims appended hereto and their equivalents.

What is claimed is:

1. A method of cleaning a semiconductor processing chamber having materials deposited therein, comprising:
introducing one or more etch gases into the chamber;
performing a first cleaning process to remove the deposited materials at a high rate; and
performing a second cleaning process to remove the deposited materials at a high etch selectivity with respect to the material forming the chamber.

2. The method of claim 1 wherein the first cleaning process is performed at a first pressure, the second cleaning process is performed at a second pressure, and the second pressure is lower than the first pressure.

3. The method of claim 2 wherein the first pressure is from about 100 to about 700 Torr and the second pressure is from about 5 to about 100 Torr.

4. The method of claim 3 wherein the first pressure is from about 300 to about 700 Torr and the second pressure is from about 5 to about 50 Torr.

5. The method of claim 1 wherein the first and second cleaning processes are performed at a substantially same temperature.

6. The method of claim 5 wherein the first and second cleaning processes are performed at a temperature ranging from about 500 to about 800° C.

7. The method of claim 1 wherein said one or more etch gases comprise nitrogen fluoride (NF₃).

8. The method of claim 7 wherein said one or more etch gases further comprise oxygen and one or more inert gases.

9. The method of claim 1 wherein said one or more etch gases comprise one or more fluorine containing gases.

10. The method of claim 1 wherein said one or more etch gases are selected from the group consisting of NF₃, CF₄, C₂F₆, C₃F8, F₂, ClF₃, (CF₃CO)₂O, C₄F₈O, C₄F₈, anhydrous HF, CHF₃, and mixtures thereof.

11. The method of claim 1 wherein the first cleaning process is performed at a high etch rate ranging from about 0.1 to about 15 micron/min.

12. The method of claim 1 wherein the materials deposited in the chamber are selected from the group consisting of silicon nitride, silicon oxide, silicon oxynitride, silicon carbide, polysilicon, amorphous silicon, germanium, Ge-doped polysilicon, refractory metals, metal nitrides, metal oxynitrides, metal silicides, metal oxide, metal carbides, and metal silicates.

13. The method of claim 1 wherein the chamber is made of quartz, the material deposited in the chamber is silicon nitride and the second cleaning process is preformed at an etch selectivity of about 2:1 to about 300:1 silicon nitride to quartz.

14. The method of claim 1 wherein the chamber is made of quartz, the material deposited in the chamber is polysilicon, and the second cleaning process is preformed at an etch selectivity of about 5:1 to 2000:1 polysilicon to quartz.

15. The method of claim 1 wherein the chamber includes wafer carrier components having undesired materials deposited thereon, said components being provided with load and processing positions, and
wherein the first cleaning process is performed in the processing position, and the second cleaning processes is performed in the load position, or in the processing position.

16. The method of claim 1 wherein the chamber is a single-wafer hot-wall rapid thermal chemical vapor deposition reactor.

17. A method of in situ cleaning a chemical vapor deposition chamber and associated components, said chamber and components having undesired materials deposited thereon during processing, the method comprising the steps of:
positioning the components within the chamber in a processing position substantially the same as during processing;
introducing an etch gas into the chamber at a temperature substantially the same as during processing;
performing a first cleaning process at a first pressure to remove the deposited materials at a high etch rate; and
performing a second cleaning process at a second pressure to remove the deposited materials at a high etch selectivity with respect to the materials forming the chamber and components;
wherein the second pressure of the second cleaning process is lower than the first pressure of the first process.

18. The method of claim 17 wherein the first cleaning process is preformed at a pressure from about 100 to about 700 Torr, and the second cleaning process is performed at a pressure from about 5 to about 100 Torr.

19. The method of claim 17 wherein said etch gas is selected from the group consisting of NF₃, CF₄, C₂F₆, C₃F₈, F₂, ClF₃, (CF₃CO)₂O, C₄F₈O, C₄F₈, anhydrous HF, CHF₃, and mixtures thereof.

20. The method of claim 17 wherein the materials deposited in the chamber and components are selected from the group consisting of silicon nitride, silicon oxide, silicon oxynitride, silicon carbide, polysilicon, amorphous silicon, germanium, Ge-doped polysilicon, refractory metals, metal nitrides, metal oxynitrides, metal suicides, metal oxide, metal carbides, and metal silicates.
